(19) United States
(12) Patent Application Publication
(10) Pub. No.: US 2026/0013249 A1
(43) Pub. Date: Jan. 8, 2026

(54) IMAGE SENSOR

(71) Applicant: SAMSUNG ELECTRONICS CO., LTD., Suwon-si (KR)

(72) Inventors: Sangin BAE, Suwon-si (KR); Yun Ki LEE, Suwon-si (KR); Hyeyeon PARK, Suwon-si (KR); Hyunkyu CHOI, Suwon-si (KR)

(73) Assignee: SAMSUNG ELECTRONICS CO., LTD., Suwon-si (KR)

(21) Appl. No.: 19/202,625

(22) Filed: May 8, 2025

(30) Foreign Application Priority Data
Jul. 4, 2024 (KR) 10-2024-0088463

(51) Int. Cl. H10F 39/00; H10F 39/18

(52) U.S. Cl. CPC H10F 39/8053; H10F 39/024; H10F 39/182; H10F 39/805; H10F 39/807

(57) ABSTRACT

An image sensor may include a substrate including a central area and an edge area surrounding the central area, the substrate including a plurality of photodiodes in the central area and the edge area, a plurality of center color filters provided on the plurality of photodiodes in the central area, a plurality of edge color filters provided on the plurality of photodiodes in the edge area, and an air grid pattern provided between the plurality of center color filters and/or between the plurality of edge color filters, wherein portions the plurality of center color filters have a convex shape with respect to an upper surface of the substrate, and wherein upper surfaces of the plurality of edge color filters have a different shape from upper surfaces of the plurality of center color filters.

### CROSS-REFERENCE TO RELATED APPLICATION

This application is based on and claims priority to Korean Patent Application No. 10-2024-0088463 filed in the Korean Intellectual Property Office on Jul. 4, 2024, the disclosure of which is herein incorporated by reference in its entirety.

### BACKGROUND

### 1. Field

One or more example embodiments of the disclosure relate to an image sensor.

### 2. Description of the Related Art

A complementary metal-oxide semiconductor (CMOS) image sensor is a solid-state imaging device using a CMOS. Compared to a charge coupled device (CCD) image sensor with high-voltage analog circuit, the CMOS image sensor has advantages of low manufacturing cost and low power consumption due to a small size of the CMOS image sensor. Thus, the CMOS image sensor is mainly installed in home appliances in addition to portable devices such as smartphones and digital cameras.

A pixel array included in the CMOS image sensor includes a photodiode in each pixel. The photodiode generates an electrical signal that varies depending on an amount of incident light, and the CMOS image sensor processes the electrical signal to synthesize an image.

The CMOS image sensor includes a color filter array (CFA), for example, primary or complementary color filters, and may detect color information by transmitting light with a specific wavelength band through the color filter array.

Recently, as a demand for a high-resolution image has increased, there is a need for a color filter array that is advantageous in terms of resolution and has a structure and arrangement capable of expressing various colors.

### SUMMARY

One or more example embodiments of the disclosure provide an image sensor having an improved optical characteristic.

According to an aspect of an example embodiment of the disclosure, provided is an image sensor including: a substrate including a central area and an edge area surrounding the central area, the substrate including a plurality of photodiodes in the central area and the edge area, a plurality of center color filters provided on the plurality of photodiodes in the central area, a plurality of edge color filters provided on the plurality of photodiodes in the edge area, and an air grid pattern provided between the plurality of center color filters and/or between the plurality of edge color filters, wherein portions of the plurality of center color filters have a convex shape with respect to an upper surface of the substrate, and wherein upper surfaces of the plurality of edge color filters have a different shape from upper surfaces of the plurality of center color filters.

According to an aspect of an example embodiment of the disclosure, provided is an image sensor including: a substrate including a plurality of photodiodes; a plurality of color filters provided on the plurality of photodiodes, and spaced apart from each other, portions of the plurality of color filters having a curved surface shape that is convex with respect to an upper surface of the substrate; and an air grid pattern provided between the plurality of color filters.

According to an aspect of an example embodiment of the disclosure, provided is an image sensor including: a substrate including a central area and an edge area surrounding the central area, the substrate including a plurality of photodiodes in the central area and the edge area; a plurality of center color filters provided on the plurality of photodiodes in the central area, the plurality of center color filters being spaced apart from each other; a plurality of edge color filters provided on the plurality of photodiodes in the edge area, the plurality of edge color filters being spaced apart from each other; capping layers provided on the plurality of center color filters and the plurality of edge color filters, respectively, the clapping layers being spaced apart from each other; and an air grid pattern provided between the plurality of center color filters and/or between the plurality of edge color filters, wherein upper surfaces of the plurality of center color filters include a curved surface that is convex with respect to an upper surface of the substrate, wherein each edge color filter of the plurality of edge color filters includes a first portion and a second portion, wherein an upper surface of the first portion has a first curvature, and wherein an upper surface of the second portion has a second curvature different from the first curvature.

### BRIEF DESCRIPTION OF THE DRAWINGS

Example embodiments will be more clearly understood from the following detailed description taken in conjunction with the accompanying drawings in which:

FIG. 1 is a block diagram of an image sensor according to an embodiment;

FIG. 2 is a top plan view of an image sensor according to an embodiment;

FIG. 3 is a top plan view showing a central area and an edge area of an image sensor according to an embodiment;

FIG. 4 is a cross-sectional view taken along line A-A′ of FIG. 3;

FIG. 5 is an enlarged cross-sectional view of region Q1 of FIG. 4;

FIG. 6 is a cross-sectional view taken along line B-B′ of FIG. 3;

FIG. 7 is an enlarged cross-sectional view of region Q2 of FIG. 6;

FIG. 8 to FIG. 11 are cross-sectional views showing an image sensor according to some embodiments, corresponding to the region Q1 of FIG. 4;

FIG. 12 and FIG. 13 are cross-sectional views showing an image sensor according to some embodiments, corresponding to the region Q2 of FIG. 6;

FIG. 14 is a top plan view showing a central area and an edge area of an image sensor according to some embodiments;

FIG. 15 is a cross-sectional view showing an intermediate step of a manufacturing method of a color filter according to an embodiment;

FIG. 16 is a top plan view showing a mask of an image sensor according to an embodiment;

FIG. 17 and FIG. 18 are cross-sectional views showing an intermediate step of a manufacturing method of a color filter according to some embodiments;

FIG. 19 is a top plan view showing a mask of an image sensor according to some embodiments;

FIG. 20 is a cross-sectional view showing an intermediate step of a manufacturing method of a color filter according to some embodiments;

FIG. 21 is a top plan view showing a mask of an image sensor according to some embodiments;

FIG. 22 is a cross-sectional view showing an intermediate step of a manufacturing method of a color filter according to some embodiments;

FIG. 23 is a top plan view showing a mask of an image sensor according to some embodiments; and

FIG. 24 and FIG. 25 are cross-sectional views showing an intermediate step of a manufacturing method of a color filter according to some embodiments.

### DETAILED DESCRIPTION

Hereinafter, one or more example embodiments of the disclosure will be described more fully hereinafter with reference to the accompanying drawings. As those skilled in the art would realize, the described embodiments may be modified in various different ways, all without departing from the spirit or scope of the disclosure.

In order to clearly describe the disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for better understanding and ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

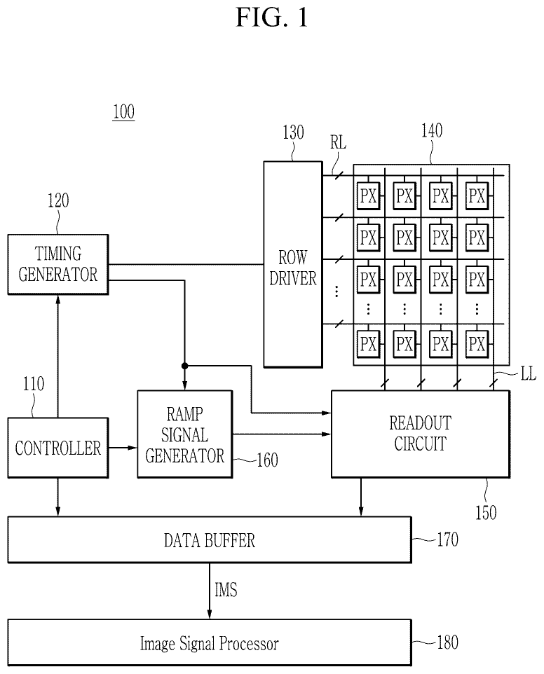

Hereinafter, an image sensor according to an embodiment will be described in detail with reference to FIG. 1.

FIG. 1 is a block diagram of an image sensor according to an embodiment.

Referring to FIG. 1, an image sensor 100 according to an embodiment may include a controller 110, a timing generator 120, a row driver 130, a pixel array 140, a readout circuit 150, a ramp signal generator 160, a data buffer 170 and an image signal processor 180. In an embodiment, the image signal processor 180 may be located outside the image sensor 100.

The image sensor 100 may generate an image signal IMS by converting light received from an outside into an electrical signal. The image signal IMS may be provided to the image signal processor 180.

The image sensor 100 may be mounted on an electronic device having an image capturing function and/or optical sensing function. For example, the image sensor 100 may be mounted on an electronic device such as a camera, a smartphone, a wearable device, an Internet of things (IoT) device, a home appliance, a tablet personal computer (PC), a navigation device, a drone, an advanced driver assistance systems (ADAS), and the like. In addition, the image sensor 100 may be mounted on an electronic device provided as a component in a vehicle, furniture, a manufacturing facility, a door, various measurement devices, or the like.

The controller 110 may generally control respective components 120, 130, 150, 160, and 170 included in the image sensor 100. The controller 110 may control respective operation timings of the components 120, 130, 150, 160, and 170 by using control signals. In an embodiment, the controller 110 may receive a mode signal indicating an imaging mode from an application processor, and may overall control the image sensor 100 based on the received mode signal. For example, the application processor may determine the imaging mode of the image sensor 100 according to various scenarios such as an illumination of an imaging environment, a user's resolution setting, a sensed and/or learned state, or the like, and provide the determined imaging mode to the controller 110 as the mode signal. The controller 110 may control a plurality of pixels of the pixel array 140 to output a pixel signal according to the imaging mode, the pixel array 140 may output a pixel signal with respect to each of the plurality of pixels or a pixel signal with respect to a portion of the plurality of pixels, and the readout circuit 150 may sample and process pixel signals output from the pixel array 140. The timing generator 120 may generate a signal serving as a reference for operation timing of components of the image sensor 100. The timing generator 120 may control the timing of the row driver 130, the readout circuit 150, and the ramp signal generator 160. The timing generator 120 may provide a control signal that controls the timing of the row driver 130, the readout circuit 150 and the ramp signal generator 160.

The pixel array 140 may include the plurality of pixels PX, and a plurality of row lines RL and a plurality of column lines LL connected to the plurality of pixels PX, respectively. In an embodiment, each pixel PX may include at least one photoelectric conversion device. The photoelectric conversion device may detect incident light, and may convert incident light to an electric signal according to an amount of light, e.g., a plurality of analog pixel signals. The photoelectric conversion device may be a photodiode, a pinned diode, or the like.

In addition, the photoelectric conversion device may include a single-photon avalanche diode (SPAD) applied to a three-dimensional (3D) sensor pixel. A level of the analog pixel signals output from the photoelectric conversion device may be proportional to an amount of charges output from the photoelectric conversion device. That is, the level of the analog pixel signals output from the photoelectric conversion device may be determined according to the amount of light received into the pixel array 140.

The plurality of row lines RL may extend in a first direction, and may be connected to the pixels PX disposed along the first direction. For example, the control signal output from the row driver 130 to a row line RL may be transferred to a gate of a transistor of each of the plurality of pixels PX connected to the corresponding row line RL. A column line LL may extend in a second direction crossing the first direction, and may be connected to the plurality of pixels PX disposed along the second direction. The plurality of pixel signals output from the plurality of pixels PX may be transferred to the readout circuit 150 through the plurality of column lines LL.

A color filter layer may be located on the pixel array 140. The color filter layer may include color filters such as red, green, and blue filters, and additionally, may further include white and complementary colors. A color filter of one color may be located with respect to one pixel PX, but the disclosure is not limited thereto.

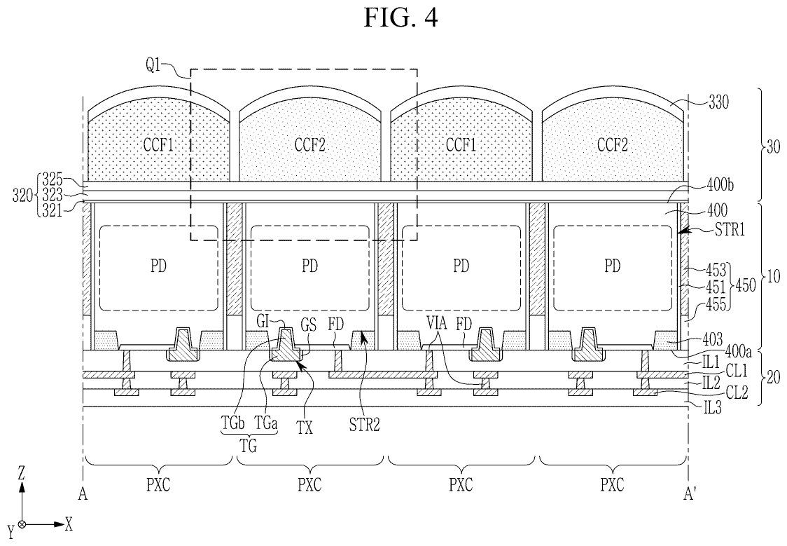

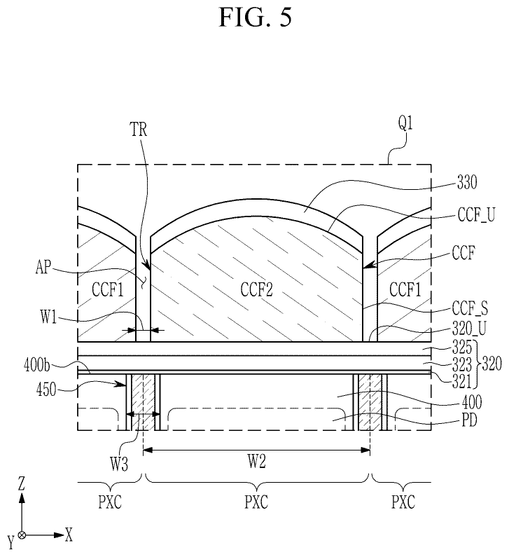

A microlens layer may not be located on the color filter layer of an image sensor according to an embodiment. In an embodiment, the color filter layer may perform a function of concentrating the light incident from the outside onto the plurality of pixels PX. This will be described later with reference to FIG. 4 and FIG. 5.

The row driver 130 may generate a control signal for driving the pixel array 140 based on the control signal of the timing generator 120, and may provide the control signal to the plurality of pixels PX of the pixel array 140 through the plurality of row lines RL.

In an embodiment, the row driver 130 may control the pixel PX to detect the incident light on a row line basis (or according to a row line unit). The row line unit may include at least one row line RL. For example, the row driver 130 may provide a transmission signal, a reset signal, a selection signal, or the like to the pixel array 140 to the pixel array 140.

The readout circuit 150 may convert the pixel signal (or electric signal) received from the pixels PX connected to the row line RL selected from among the plurality of pixels PX to a pixel value representing the amount of light, based on a control signal received from the timing generator 120. The readout circuit 150 may convert the pixel signal output through the corresponding column line LL to the pixel value. For example, the readout circuit 150 may compare a ramp signal and the pixel signal, and convert the pixel signal to the pixel value based on a result of comparison. The pixel value may be an image data having a plurality of bits. Specifically, the readout circuit 150 may include a selector, a plurality of comparators, and a plurality of counter circuits.

The ramp signal generator 160 may generate a reference signal and transmit the reference signal to the readout circuit 150.

The ramp signal generator 160 may include a current source (e.g., a variable current source), a resistor (e.g., a variable resistor), and a capacitor. The ramp signal generator 160 may adjust a ramp voltage, which is a voltage applied to a ramp resistor, by adjusting a current amount of the variable current source or a resistance value of the variable resistor, such that the ramp signal generator 140 may generate a plurality of ramp signals that fall or rise with a slope determined according to the current amount of the variable current source or the resistance value of the variable resistor.

The data buffer 170 may store the pixel value of each of the plurality of pixels PX connected to the selected column line LL transferred from the readout circuit 150, and output the stored pixel value based on an enable signal from the controller 110.

The image signal processor 180 may perform image signal processing on the image signal received from the data buffer 170. For example, the image signal processor 180 may receive a plurality of image signals from the data buffer 170, and generate one image by synthesizing the received image signals.

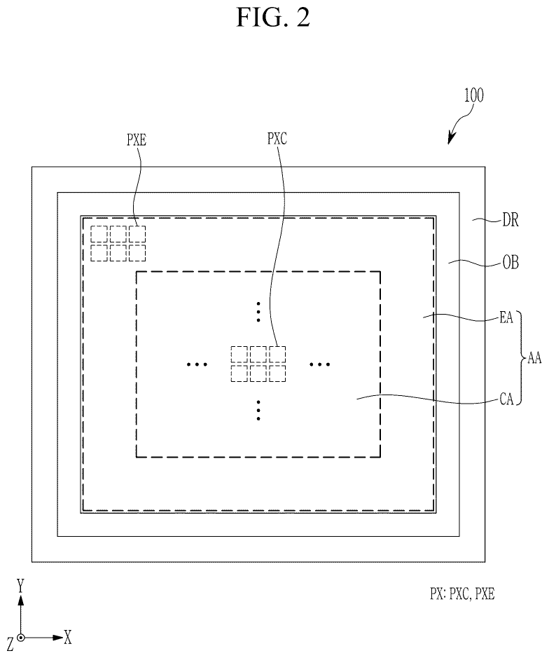

Hereinafter, referring to FIG. 2 to FIG. 7, an image sensor according to one or more example embodiments will be described.

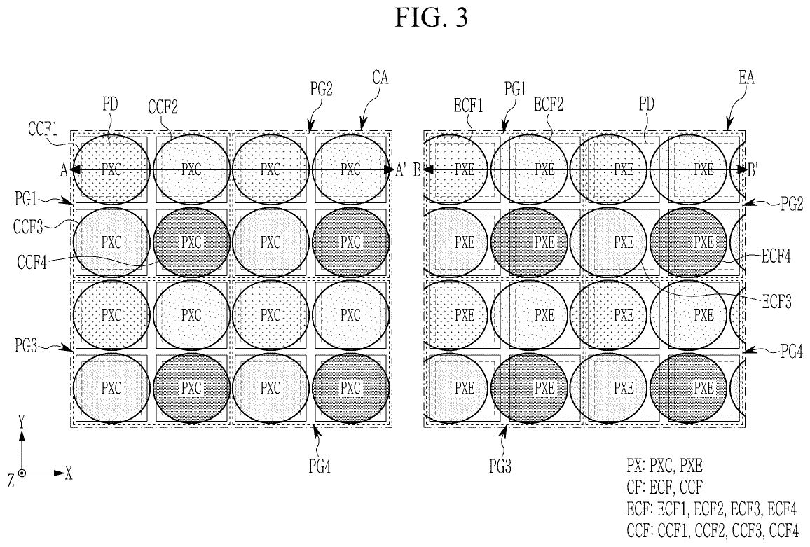

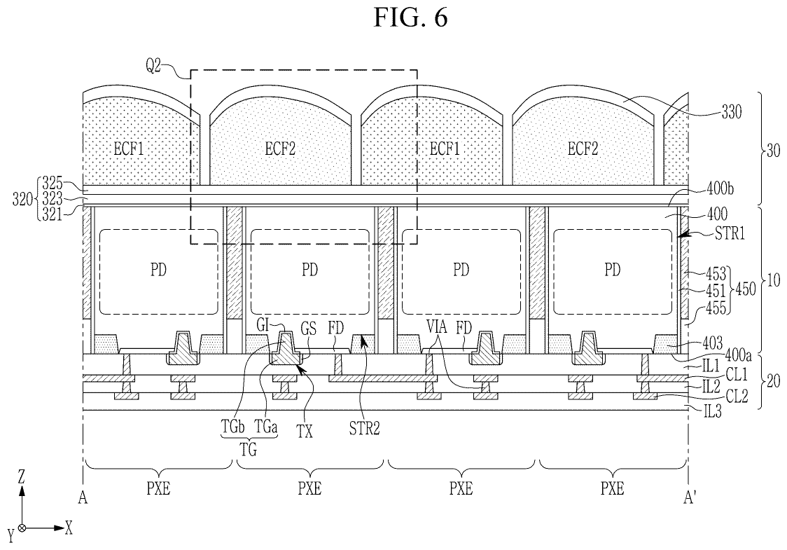

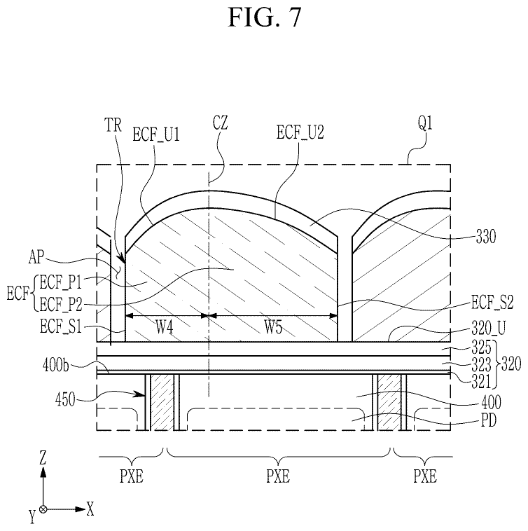

FIG. 2 is a top plan view of an image sensor according to an embodiment. FIG. 3 is a top plan view showing a central area and an edge area of an image sensor according to an embodiment. FIG. 4 is a cross-sectional view taken along line A-A′ of FIG. 3. FIG. 5 is an enlarged cross-sectional view of region Q1 of FIG. 4. FIG. 6 is a cross-sectional view taken along line B-B′ of FIG. 3. FIG. 7 is an enlarged cross-sectional view of region Q2 of FIG. 6. For convenience of description, FIG. 4 and FIG. 5 illustrate a center pixel PXC located in a central area CA, and FIG. 6 and FIG. 7 illustrate an edge pixel PXE located in an edge area EA.

First, referring to FIG. 2 to FIG. 4, an image sensor according to an embodiment may include a photoelectric conversion layer 10, a wire area 20, and a light transmitting layer 30.

The photoelectric conversion layer 10 may be located between the wire area 20 and the light transmitting layer 30. That is, the wire area 20, the photoelectric conversion layer 10, and the light transmitting layer 30 may be sequentially located along a third direction (Z direction).

The photoelectric conversion layer 10 may include a substrate 400 and photodiodes PD located within the substrate 400. The light incident from the outside may be converted into electrical signals by each of the photodiodes PD.

The substrate 400 may include a first surface 400a and a second surface 400b facing each other in the third direction (Z direction), which is the vertical direction. The second surface 400b of the substrate 400 may be a light receiving surface on which the light is incident.

As shown in FIG. 2, the substrate 400 may include a pixel array area AA and an optical black area OB, in a plan view. The pixel array area AA may be located in a generally central portion of the substrate 400, in a plan view. The pixel array area AA may include the plurality of pixels PX. The pixel PX may output the photoelectric signal generated based on the incident light. The plurality of pixels PX may be arranged in rows parallel to each other along the first direction (X direction) and columns parallel to each other along the second direction (Y direction).

In an embodiment, the pixel array area AA may include the central area CA and the edge area EA. The central area CA may be located in the generally central portion of the pixel array area AA. The central area CA may include a plurality of center pixels PXC. The plurality of center pixels PXC may mean pixels located in the central area CA among the plurality of pixels PX.

The edge area EA may be located on an outer side of the central area CA. The edge area EA may be located in a generally edge portion of the pixel array area AA. For example, the edge area EA may surround the central area CA, but is not limited thereto. The edge area EA may include a plurality of edge pixels PXE. The plurality of edge pixels PXE may mean pixels located in the edge area EA. In other words, as shown in FIG. 3, the plurality of pixels PX according to an embodiment may include the center pixel PXC located in the central area CA and the edge pixel PXE located in the edge area EA.

Hereinafter, for better understanding and ease of description, the pixel located in the central area CA will be referred to as the center pixel PXC, and the pixel located in the edge area EA will be referred to as the edge pixel PXE.

The optical black area OB may be located on an outer side of the pixel array area AA. The optical black area OB may surround the pixel array area AA, but is not limited thereto. The optical black area OB may include a dummy area. A signal generated in the dummy area may be used as information for removing a process noise afterwards.

An image sensor according to an embodiment may further include a pad region DR located on an outer side of the optical black area OB. The pad region DR may surround the optical black area OB, but is not limited thereto. A plurality of pad terminals may be located in the pad region. The plurality of pad terminals may output the electrical signal generated by the pixel PX to the outside. Alternatively, an electrical signal or voltage generated from the outside may be transferred to the pixel PX through the plurality of pad terminals.

The substrate 400 may include a semiconductor substrate or a silicon-on-Insulator (SOI) substrate. The semiconductor substrate may include, for example, a silicon substrate, a germanium substrate, or a silicon-germanium substrate. The substrate 400 may include impurities of a first conductivity type. For example, impurities of the first conductivity type may be P-type impurities such as aluminum (Al), boron (B), indium (In) and/or gallium (Ga).

The substrate 400 may include the plurality of pixels PX defined by a pixel separation pattern 450 to be described later. For example, the substrate 400 may include the plurality of center pixels PXC defined by the pixel separation pattern 450 in the central area CA and the plurality of edge pixels PXE defined by the pixel separation pattern 450 in the edge area EA. The plurality of pixels PX may output the photoelectric signal based on the incident light incident from the outside.

The plurality of pixels PX may be arranged along rows and columns, in a plan view. That is, the plurality of pixels PX may be arranged in a matrix shape along rows parallel to the first direction (X direction) and columns parallel to the second direction (Y direction), in a plan view. For example, as shown in FIG. 3, the plurality of center pixels PXC may be arranged along the first direction (X direction) and the second direction (Y direction) in the central area CA, and the plurality of edge pixels PXE may be arranged along the first direction (X direction) and the second direction (Y direction) in the edge area EA.

As shown in FIG. 3, the plurality of pixels PX may configure first to fourth pixel groups PG1, PG2, PG3, and PG4. For example, the plurality of center pixels PXC may configure the first to fourth pixel groups PG1, PG2, PG3, and PG4, and the plurality of edge pixels PXE may configure the first to fourth pixel groups PG1, PG2, PG3, and PG4. That is, the first to fourth pixel groups PG1, PG2, PG3, and PG4 may include N×M pixels PXs arranged in an N×M array. The N and the M may be integers greater than 1. For example, the first to fourth pixel groups PG1, PG2, PG3, and PG4 may include four adjacent pixels PX arranged in two rows and two columns, respectively. However, the number and arrangement of the pixel PX included in one pixel group is not limited thereto, and may be changed in various manners. For example, each of the first to fourth pixel groups PG1, PG2, PG3, and PG4 may include nine adjacent pixels PX arranged in three rows and three columns, respectively. As another example, each of the first to fourth pixel groups PG1, PG2, PG3, and PG4 may include sixteen adjacent pixels PX arranged in four rows and four columns, respectively.

A plurality of photodiodes PD may be located within the substrate 400, and may accommodate light. The plurality of photodiodes PD may be located to correspond to each of the plurality of pixels PX. That is, the plurality of photodiodes PD may have substantially the same arrangement as the plurality of pixels PX, in a plan view. For example, as shown in FIG. 4, the plurality of photodiodes PD may be located to correspond to each of the plurality of center pixels PXC located in the central area CA. Alternatively, as shown in FIG. 6, the plurality of photodiodes PD may be located to correspond to each of the plurality of edge pixels PXE located in the edge area EA. Light incident from the outside onto the photodiodes PD may be converted into electrical signals by the photodiodes PD. The photodiodes PD may generate and accumulate photo-charges, proportionally to intensity of the incident light.

The photodiodes PD may be a region doped with impurities of a second conductivity type within the substrate 400. The impurities of the second conductivity type may have an opposite conductivity type to the impurities of the first conductivity type. The impurities of the second conductivity type may include N-type impurities such as phosphorus, arsenic, bismuth, and/or antimony.

Each of the photodiodes PD may include a first region adjacent to the first surface 400a of the substrate 400 and a second region adjacent to the second surface 400b. There may be an impurity concentration difference between the first region and the second region of the photodiodes PD. Accordingly, the photodiodes PD may have a potential slope between the first surface 400a and the second surface 400b of the substrate 400. However, in some embodiments, the photodiodes PD may not have a potential slope between the first surface 400a and the second surface 400b of the substrate 400.

An image sensor according to an embodiment may further include the pixel separation pattern 450 located between the plurality of photodiodes PD.

The pixel separation pattern 450 may be located between the plurality of pixels PX. For example, the pixel separation pattern 450 may be located between the plurality of center pixels PXC, between the plurality of edge pixels PXE, and between the plurality of center pixels PXC and the plurality of edge pixels PXE. The pixel separation pattern 450 may define the plurality of pixels PX included in the first to fourth pixel groups PG1, PG2, PG3, and PG4. That is, the pixel separation pattern 450 may have a lattice structure, in a plan view, and may partition the plurality of pixels PX included in the first to fourth pixel groups PG1, PG2, PG3, and PG4. The pixel separation pattern 450 may be located between the plurality of photodiodes PD.

The pixel separation pattern 450 may be located within a first substrate trench STR1 in a cross-section. The pixel separation pattern 450 may include a deep trench isolation (DTI) layer. The pixel separation pattern 450 may penetrate the substrate 400. A thickness of the pixel separation pattern 450 may be substantially the same as a thickness of the substrate 400 along the vertical direction of the substrate 400.

Although FIG. 4 and FIG. 6 illustrate that a width along the first direction (X direction) of the pixel separation pattern 450 is constant within the substrate 400, a shape of the pixel separation pattern 450 on a cross-section is not limited thereto, and may be changed in various ways. For example, the pixel separation pattern 450 may have a shape in which the width along the first direction (X direction) gradually decreases from the first surface 400a of the substrate 400 to the second surface 400b.

The pixel separation pattern 450 may include a first separation pattern 451, a second separation pattern 453 and a capping pattern 455.

The first separation pattern 451 may extend along an inner surface of the first substrate trench STR1. The first separation pattern 451 may include a silicon-based insulating material (e.g., silicon nitride, silicon oxide or silicon oxidation nitride) or a high-K material (e.g., hafnium oxide or aluminum oxide). As another example, the first separation pattern 451 may include a plurality of layers, and two or more of the plurality of layers or respective layers of the plurality of layers may include different materials. The first separation pattern 451 may have a lower refractive index than the substrate 400. However, a material included in the first separation pattern 451 is not limited thereto, and may be changed in various ways. Accordingly, a crosstalk phenomenon between the pixels PX located in the first substrate 400 may be prevented or decreased.

The second separation pattern 453 may be located on the side surface of first separation pattern 451. Both side surfaces of the second separation pattern 453 may be surrounded by the first separation pattern 451. The first separation pattern 451 may be located between the second separation pattern 453 and the substrate 400. The second separation pattern 453 may be spaced apart from the substrate 400 by the first separation pattern 451.

Accordingly, when the image sensor 100 operates, the second separation pattern 453 may be electrically separated from the substrate 400. The second separation pattern 453 may include a crystalline semiconductor material such as polycrystalline silicon, and the second separation pattern 453 may further include a dopant, and the dopant may include the impurities of the first conductivity type or impurities of the second conductivity type. As another example, the second separation pattern 453 may include doped polycrystalline silicon. As a still another example, the second separation pattern 453 may include an undoped crystalline semiconductor material. As a still another example, the second separation pattern 453 may include undoped polycrystalline silicon. The term “undoped” may mean that no intentional doping process is to be performed. The dopant may include an N-type dopant and a P-type dopant. However, the material included in the second separation pattern 453 is not limited thereto, and may be changed in various ways.

The capping pattern 455 may be located on a bottom surface of the second separation pattern 453. The second separation pattern 453 and the capping pattern 455 may be located to overlap in the vertical direction, and the capping pattern 455 may be disposed adjacent to the first surface 400a of the substrate 400.

The capping pattern 455 may include a non-conductive material. The capping pattern 455 may include a silicon-based insulating material (e.g., silicon nitride, silicon oxide or silicon oxidation nitride) or a high-K material (e.g., hafnium oxide or aluminum oxide). However, a material included in the capping pattern 455 is not limited thereto, and may be changed in various ways.

Accordingly, the pixel separation pattern 450 may prevent photo-charges generated by the incident light incident onto the pixel PX from being incident onto another adjacent pixel PX due to random drift. That is, the pixel separation pattern 450 may prevent a crosstalk phenomenon between the pixels PX.

An image sensor according to an embodiment may further include a device isolation pattern 403 located within the substrate 400.

The device isolation pattern 403 may be located within the substrate 400. For example, the device isolation pattern 403 may be located within a second substrate trench STR2, on a cross-section. The second substrate trench STR2 may be recessed from the first surface 400a of the substrate 400 toward the second surface 400b. The device isolation pattern 403 may include a shallow trench isolation (STI) layer.

The device isolation pattern 403 may define an active pattern. An upper surface of the device isolation pattern 403 may be located within the substrate 400. A width of the device isolation pattern 403 along the first direction (X direction) may gradually decrease from the first surface 400a of the substrate 400 to the second surface 400b. The upper surface of the device isolation pattern 403 may be located to be spaced apart from the photodiodes PD.

A transmission transistor TX including a transfer gate TG may be located on the first surface 400a of the substrate 400. In an embodiment, the transfer gate TG may be a Vertical Type. A portion of the transfer gate TG may be located within the substrate 400, and a remaining portion may protrude above the first surface 400a of the substrate 400.

For example, the transfer gate TG may include a first portion TGa of the transfer gate TG located on the first surface 400a of the substrate 400 and a second portion TGb of the transfer gate TG located within the substrate 400 and extending from the first surface 400a of the substrate 400 toward the second surface 400b. However, a shape of the transfer gate TG is not limited thereto, and may be changed in various ways. For example, the transfer gate TG may not be provided with the second portion TGb, and may be a planar type which includes only the first portion TGa.

Although not shown in FIG. 4 and FIG. 6, an amplification transistor and a selection transistor may be located on the first surface 400a of the substrate 400. A gate of the amplification transistor and a gate of the selection transistor may be located on the first surface 400a of the substrate 400.

In addition, although not shown in FIG. 4 and FIG. 6, a reset transistor and a dual conversion transistor may be located on the first surface 400a of the substrate 400. The reset transistor may include a reset gate, and the dual conversion transistor may include a dual conversion gate.

A gate spacer GS may be located on both side surfaces of the first portion TGa of the transfer gate TG. The gate spacer GS may include, for example, silicon nitride, silicon carbonization nitride or silicon oxidation nitride.

A gate dielectric layer GI may be located between the transfer gate TG and the substrate 400. For example, the gate dielectric layer GI may be located between the second portion TGb and the substrate 400 of the transfer gate TG.

Although not shown in FIG. 4 and FIG. 6, the gate dielectric layer GI may be located between the dual conversion gate and the substrate 400, and between the reset gate and the substrate 400, and the gate spacer GS may be located on both side surfaces of the above-described dual conversion and reset gates.

In some embodiments, a substrate overlapping with and opposing the substrate 400 may be further included, and at least one of the amplification transistor, the selection transistor, the reset transistor, and the dual conversion transistor may be located on the opposing substrate. In such a case, at least one of the amplification transistor, the selection transistor, the reset transistor, and the dual conversion transistor located on the opposing substrate and the transmission transistor TX located on the substrate 400 may be connected by a connection node.

An image sensor according to an embodiment may further include a floating diffusion region FD located within the substrate 400.

The floating diffusion region FD may be located within the substrate 400. The charges charged in the photodiodes PD may be transferred to the floating diffusion region FD. The floating diffusion region FD may maintain the charges transferred from the photodiode PD.

The floating diffusion region FD may be located adjacent to the first surface 400a of the substrate 400. The floating diffusion region FD may be located to be buried from the first surface 400a of the substrate 400 toward the second surface 400b. The floating diffusion region FD may be connected to a first terminal of the transmission transistor TX.

The first wire area 20 may be located on the first surface 400a of the substrate 400, and may include a plurality of insulation layers IL1, IL2, and IL3, a plurality of wire layers CL1 and CL2 and a via VIA.

The insulation layer may include a first insulation layer IL1, a second insulation layer IL2 and a third insulation layer IL3. The first insulation layer IL1, the second insulation layer IL2, and the third insulation layer IL3 may sequentially stacked on the first surface 400a of the substrate 400.

The first insulation layer IL1 may cover the first surface 400a of the substrate 400. The first insulation layer IL1 may cover the first portion TGa of the transfer gate TG. The second insulation layer IL2 may located on the first insulation layer IL1. The third insulation layer IL3 may located on the second insulation layer IL2.

The first to the third insulation layers IL1, IL2, and IL3 may include an insulating material. For example, the first to third insulation layers IL1, IL2, and IL3 may include a silicon-based insulating material such as silicon oxide, silicon nitride or silicon oxidation nitride.

The first wire area 20 may include a first wire layer CL1 and a second wire layer CL2. The first wire layer CL1 may be located within the second insulation layer IL2. The second wire layer CL2 may be located within the third insulation layer IL3.

A plurality of vias VIA may be located within the first insulation layer IL1, the second insulation layer IL2, the third insulation layer IL3. The via VIA may interconnect the floating diffusion region FD, the first wire layer CL1 and the second wire layer CL2.

The first wire layer CL1, the second wire layer CL2 and the via VIA may include a metal material. For example, the first wire layer CL1, the second wire layer CL2 and the via VIA may include copper (Cu)

The light transmitting layer 30 may be located on the second surface 400b of the substrate 400. The light transmitting layer 30 may collect and filter the light incident from the outside, and provide the light to the photodiodes PD.

The light transmitting layer 30 of an image sensor according to an embodiment may include a plurality of color filters CF.

The plurality of color filters CF may be located on the second surface 400b of the substrate 400. The plurality of color filters CF may be located on an upper surface 320_U (see FIG. 5) of a reflection preventing structure 320 to be described later. The plurality of color filters CF may be in contact with the upper surface 320_U of the reflection preventing structure 320 to be described later. The plurality of color filters CF may include a negative photoresist material, but is not limited thereto.

The plurality of color filters CF may be arranged along rows and columns to respectively correspond to the plurality of pixels PX. For example, as shown in FIG. 3, the plurality of color filters CF may be arranged along the first direction (X direction) and the second direction (Y direction) to respectively correspond to the plurality of center pixels PXC and the plurality of edge pixels PXE. Each of the plurality of color filters CF may be located in one pixel PX, respectively. The plurality of color filters CF may be located on the plurality of photodiodes PD. The plurality of color filters CF may overlap with the plurality of photodiodes PD in the third direction (Z direction). In respective pixels PX, the plurality of color filters CF may include primary color filters.

In an embodiment, the plurality of color filters CF may be positioned apart from each other. For example, the plurality of color filters CF may be positioned apart from each other in the first direction (X direction) and the second direction (Y direction).

In an embodiment, the plurality of color filters CF may be positioned apart from each other. For example, the plurality of color filters CF may be positioned apart from each other along the first direction (X direction) and the second direction (Y direction). A trench TR (see FIG. 5) may be located between the plurality of color filters CF. In an embodiment, a lower surface of the trench TR (see FIG. 5) may be defined as the upper surface 320_U of the reflection preventing structure 320 to be described later. A side surface of the trench TR (see FIG. 5) may be defined as a side surface of the plurality of color filters CF. In an embodiment, the trench TR (see FIG. 5) may expose at least a portion of the side surface of the plurality of color filters CF. In an embodiment, an air grid pattern AP (see FIG. 5) may be located within the trench TR (see FIG. 5). The trench TR (see FIG. 5) and the air grid pattern AP (see FIG. 5) will be described later in detail.

In an embodiment, the plurality of color filters CF may include a plurality of center color filters CCF located in the central area CA and a plurality of edge color filters ECF located in the edge area EA.

Here, the center color filter CCF may mean a color filter located in the center pixel PXC in the central area CA among the plurality of color filters CF, and the edge color filter ECF may mean a color filter located in the edge pixel PXE in the edge area EA among the plurality of color filters CF.

Hereinafter, for convenience of description, the color filter located in the central area CA among the plurality of color filters CF will be referred to as the center color filter CCF, and the color filter located in the edge area EA will be referred to as the edge color filter ECF. Hereinafter, the plurality of center color filters CCF will be described in detail with reference to FIG. 3, FIG. 4, and FIG. 5.

First, referring to FIG. 3 and FIG. 4, each of the plurality of center color filters CCF may be arranged along the first direction (X direction) and the second direction (Y direction) to correspond to each of the plurality of center pixels PXC. The plurality of center color filters CCF may be located in one center pixel PXC, respectively. The plurality of center color filters CCF may be located on the plurality of photodiodes PD. The plurality of center color filters CCF may overlap with the plurality of photodiodes PD in the third direction (Z direction). A center of the plurality of center color filters CCF may be substantially coincide with a center of the plurality of photodiodes PD.

In each of the plurality of center pixels PXC, each of the plurality of center color filters CCF may include one of primary color filters. The plurality of center color filters CCF may include a first center color filter CCF1, a second center color filter CCF2, a third center color filter CCF3, and a fourth center color filter CCF4 that correspond to different colors. The first center color filter CCF1 may be a red color filter, and the second center color filter CCF2 and the third center color filter CCF3 may be a green color filter, and the fourth center color filter CCF4 may be a blue color filter. However, the disclosure is not limited thereto, for example, first to the fourth center color filter CCF4 may include a color such as cyan, magenta, or yellow. The first to the fourth center color filter CCF4 may be arranged in a Bayer pattern.

Referring further to FIG. 5, in an embodiment, the plurality of center color filters CCF may have a portion that has a convex shape with respect to the second surface 400b of the substrate 400. For example, an upper surface CCF_U of the plurality of center color filters CCF may include a curved surface that is convex with respect to the second surface 400b of the substrate 400. The upper surface CCF_U of the plurality of center color filters CCF may have a third curvature. However, the upper surface CCF_U of the plurality of center color filters CCF is not limited thereto, and as another example, the upper surface CCF_U of the plurality of center color filters CCF may include an inclined surface that is inclined at a predetermined angle from the second surface 400b of the substrate 400. As still another example, the upper surface CCF_U of the plurality of center color filters CCF may have a rectangular form that has a round edge. As still another example, the upper surface CCF_U of the plurality of center color filters CCF may include a surface parallel to the second surface 400b of the substrate 400. Accordingly, even if separate microlens are not located on the plurality of center color filters CCF, the plurality of center color filters CCF may filter the light incident from the outside, and at the same time, may refract and concentrate the light. That is, the plurality of center color filters CCF may perform the function of a lens that refracts the light incident from the outside and transfer the refracted light to the plurality of photodiodes PD.

An image sensor according to an embodiment may further include the trench TR located between the plurality of center color filters CCF and the air grid pattern AP located within the trench TR.

The trench TR may be located between the plurality of center color filters CCF. For example, the trench TR may be located between the plurality of center color filters CCF adjacent in the first direction (X direction) and between the plurality of center color filters CCF adjacent in the second direction (Y direction). The lower surface of the trench TR may be defined as the upper surface 320_U of the reflection preventing structure 320 to be described later. The side surface of the trench TR may be defined as a side surface of the plurality of center color filters CCF.

In an embodiment, the trench TR may have a lattice pattern. For example, the trench TR may extend in the first direction (X direction) and the second direction (Y direction) to be located between the plurality of center color filters CCF and/or between the plurality of edge color filters ECF. The plurality of center color filters CCF may be positioned apart from each other by the trench TR. For example, the plurality of center color filters CCF may be positioned apart from each other along the first direction (X direction) and the second direction (Y direction).

In an embodiment, the trench TR may expose at least a portion of a side surface CCF_S of the plurality of center color filters CCF. In addition, the trench TR may expose at least a portion of a side surface of a capping layer 330 to be described later. The trench TR may expose the upper surface 320_U of the reflection preventing structure 320 to be described later.

A first width W1 of the trench TR along the first direction (X direction) may be smaller than a second width W2 of the center pixel PXC along the first direction (X direction). For example, the first width W1 of the trench TR along the first direction (X direction) may be less than or equal to about ⅕ of the second width W2 along the first direction (X direction) of the center pixel PXC, but is not limited thereto. Here, the second width W2 along the first direction (X direction) of the center pixel PXC may mean a distance between centers of the pixel separation patterns 450 located on both sides of one center pixel PXC along the first direction (X direction). In addition, the first width W1 of the trench TR along the first direction (X direction) may be smaller than or equal to a third width W3 of the pixel separation pattern 450 along the first direction (X direction).

Accordingly, the air grid pattern AP may be formed within the trench TR. The air grid pattern AP may refer to a portion filled with air inside the trench TR. The air grid pattern AP may be located within the trench TR. The air grid pattern AP may completely fill an interior of the trench TR, but is not limited thereto. In an embodiment, as the air grid pattern AP is located within the trench TR, the air grid pattern AP may be located between the plurality of center color filters CCF. For example, the air grid pattern AP may be located between the plurality of center color filters CCF adjacent in the first direction (X direction) and between the plurality of center color filters CCF adjacent in the second direction (Y direction). Accordingly, the plurality of center color filters CCF may be spaced apart from each other. In an embodiment, the air grid pattern AP may have a lattice pattern. For example, the air grid pattern AP may extend in the first direction (X direction) and the second direction (Y direction) to be located between the plurality of center color filters CCF and/or between the plurality of edge color filters ECF.

The air grid pattern AP may be located on the upper surface 320_U of the reflection preventing structure 320 to be described later. The air grid pattern AP may be in contact with the upper surface 320_U of the reflection preventing structure 320, but is not limited thereto. In addition, the air grid pattern AP may be in contact with the side surface CCF_S of the plurality of center color filters CCF, but is not limited thereto.

Accordingly, the plurality of center color filters CCF of an image sensor according to an embodiment may be spaced apart from each other. In an embodiment, by the air grid pattern AP, the side surface CCF_S of the plurality of center color filters CCF may be exposed to the outside, and external air may be located between the plurality of center color filters CCF. A refractive index of the center color filters CCF may be greater than a refractive index of the air grid pattern AP located within the trench TR. When light is incident on an interface of two media having different refractive indices, the light incident at an angle greater than a threshold angle may be totally reflected. Therefore, when external light is incident on the plurality of center color filters CCF, at least a portion of the light incident toward an inner surface of the center color filters CCF (e.g., light incident on the center color filters CCF at an angle greater than the threshold angle) may be totally reflected. In an embodiment, as the air grid pattern AP has a low refractive index, a relative refractive index of the center color filter CCF may increase. Accordingly, the threshold angle of the center color filters CCF for total reflection may increase, and the light incident from the outside may be totally reflected, thereby being effectively transferred to the plurality of photodiodes PD.

Hereinafter, the plurality of edge color filters ECF will be described in detail with reference to FIG. 3, FIG. 6, and FIG. 7.

First, referring to FIG. 3 and FIG. 6, the plurality of edge color filters ECF may be arranged along the first direction (X direction) and the second direction (Y direction) to respectively correspond to the plurality of edge pixels PXE. Each of the plurality of edge color filters ECF may be located in one edge pixel PXE, respectively. The plurality of edge color filters ECF may be located on the plurality of photodiodes PD. The plurality of edge color filters ECF may overlap with the plurality of photodiodes PD in the third direction (Z direction).

In an embodiment, a center of the plurality of edge color filters ECF may be located to be offset (or deviate) from a center of the plurality of edge pixels PXE. The center of the plurality of edge color filters ECF may be spaced apart from the center of the plurality of photodiodes PD in a horizontal direction (e.g., the first direction (X direction) and the second direction (Y direction)). For example, the center of the plurality of edge color filters ECF may be spaced apart, with respect to a center of the pixel array area AA, at a greater degree than the center of the plurality of photodiodes PD that are spaced part with respect to the center of the pixel array area AA. For example, as shown in FIG. 6, the center of the plurality of edge color filters ECF may be spaced apart from the center of the plurality of photodiodes PD along the first direction (X direction), but is not limited thereto. In this way, this may compensate the fact that the light is incident at an inclined angle in an outer boundary of the image sensor, such that the light incident at the inclined angle may arrive a center portion of each pixel.

In each of the edge pixels PXE, each of the plurality of edge color filters ECF may include one of primary color filters. The plurality of edge color filters ECF may include a first edge color filter ECF1, a second edge color filter ECF2, a third edge color filter ECF3, and a fourth edge color filter ECF4 that correspond to different colors. The first edge color filter ECF1 may be a red color filter, and the second edge color filter ECF2 and the third edge color filter ECF3 may be a green color filter, and the fourth edge color filter ECF4 may be a blue color filter. However, the disclosure is not limited thereto, for example, the first to fourth edge color filters ECF1 to ECF4 may include a color such as cyan, magenta, or yellow. The first to fourth edge color filters ECF1 to ECF4 may be arranged in a Bayer pattern.

The plurality of edge color filters ECF may have a portion that has a convex shape with respect to the second surface 400b of the substrate 400. Upper surfaces of the plurality of edge color filters ECF may include a curved surface that is convex with respect to the second surface 400b of the substrate 400, but is not limited thereto.

In an embodiment, the plurality of edge color filters ECF may have a shape different from the plurality of center color filters CCF in a cross-section. The upper surfaces of the plurality of edge color filters ECF may have a different shape from upper surfaces of the plurality of center color filters CCF. For example, the upper surfaces of the plurality of edge color filters ECF may include a plurality of curved surfaces having different curvatures, and the upper surfaces of the plurality of center color filters CCF may include curved surfaces having predetermined curvatures.

Referring further to FIG. 7, the plurality of edge color filters ECF may include a first portion ECF_P1 having a first curvature and a second portion ECF_P2 having a second curvature different from the first curvature.

The first portion ECF_P1 may be located adjacent to the central area CA compared to the second portion ECF_P2. The first portion ECF_P1 may be located adjacent to the plurality of center color filters CCF compared to the second portion ECF_P2.

The first portion ECF_P1 and the second portion ECF_P2 may have a portion that has a convex shape with respect to the second surface 400b of the substrate 400. An upper surface ECF_U1 of the first portion ECF_P1 and an upper surface ECF_U2 of the second portion ECF_P2 may include a curved surface that is convex from the second surface 400b of the substrate 400, but is not limited thereto. For example, the upper surface ECF_U1 of the first portion ECF_P1 may have the first curvature, and the upper surface ECF_U2 of the second portion ECF_P2 may have the second curvature. The first curvature of the upper surface ECF_U1 of the first portion ECF_P1 may be greater than the second curvature of the upper surface ECF_U2 of the second portion ECF_P2. That is, the plurality of edge color filters ECF may include upper surfaces having different curvatures based on a reference axis CZ between the first portion ECF_P1 and the second portion ECF_P2. In addition, the first curvature of the upper surface ECF_U1 of the first portion ECF_P1 or the second curvature of the upper surface ECF_U2 of the second portion ECF_P2 may be different from the third curvature of the upper surface CCF_U of the plurality of center color filters CCF. For example, the second curvature of the upper surface ECF_U2 of the second portion ECF_P2 may be greater than the third curvature of the upper surface CCF_U of the plurality of center color filters CCF, but is not limited thereto. In addition, a fourth width W4 of the first portion ECF_P1 along the first direction (X direction) may be smaller than or equal to a fifth width W5 of the second portion ECF_P2 along the first direction (X direction) and/or the second direction (Y direction), but is not limited thereto. In this way, this may compensate the fact that the light is incident at an inclined angle in the edge area EA unlike the central area CA of the image sensor, such that the light incident at the inclined angle may arrive the center of each pixel.

As the plurality of edge color filters ECF of an image sensor according to an embodiment includes curved surfaces that are convex from the second surface 400b of the substrate 400, even if separate microlens are not located on the plurality of edge color filters ECF, the light incident from the outside may be filtered and at the same time, may be refracted and concentrated by the plurality of edge color filters ECF. That is, the plurality of edge color filters ECF may perform the function of a lens that refracts the light incident from the outside and transfer the refracted light to the plurality of photodiodes PD.

In an embodiment, the trench TR may be located between the plurality of edge color filters ECF. The lower surface of the trench TR may be defined as the upper surface 320_U of the reflection preventing structure 320 to be described later. The side surface of the trench TR may be defined as side surfaces of the plurality of edge color filters ECF. The plurality of edge color filters ECF may be positioned apart from each other by the trench TR. For example, the plurality of edge color filters ECF may be positioned apart from each other along the first direction (X direction) and the second direction (Y direction).

In an embodiment, the trench TR may expose at least a portion of the side surface of the plurality of edge color filters ECF. For example, the trench TR may expose a side surface ECF_S1 of the first portion ECF_P1 and a side surface ECF_S2 of the second portion ECF_P2.

In an embodiment, the air grid pattern AP may be located within the trench TR located between the plurality of edge color filters ECF. The air grid pattern AP may refer to a portion filled with air inside the trench TR. As the air grid pattern AP is located within the trench TR, the air grid pattern AP may be located between the plurality of edge color filters ECF. For example, the air grid pattern AP may be located between the plurality of edge color filters ECF adjacent in the first direction (X direction) and between the plurality of edge color filters ECF adjacent in the second direction (Y direction). Accordingly, the plurality of edge color filters ECF may be spaced apart from each other. In an embodiment, the air grid pattern AP may have a lattice pattern. The air grid pattern AP may be in contact with the side surface of the plurality of edge color filters ECF, but is not limited thereto.

As the air grid pattern AP having a low refractive index is located within the trench TR, a relative refractive index of the edge color filter ECF may increase. Accordingly, the threshold angle of the edge color filters ECF for total reflection may increase, and the light incident from the outside may be totally reflected, thereby being effectively transferred to the plurality of photodiodes PD. The remaining description with respect to the air grid pattern AP located between the plurality of edge color filters ECF may be substantially the same as or similar to the description with respect to the air grid pattern AP located between the plurality of center color filters CCF.

An image sensor according to an embodiment may further include the capping layer 330 located on the plurality of color filters CF.

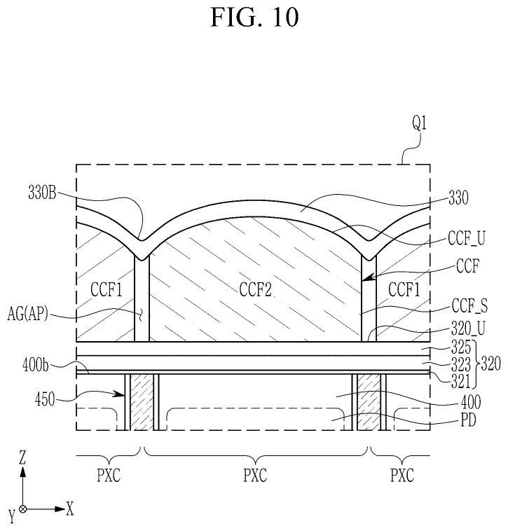

The capping layer 330 may be located on the plurality of color filters CF. For example, the capping layer 330 may be located on the plurality of center color filters CCF and the plurality of edge color filters ECF. The capping layer 330 may be conformally located on the plurality of color filters CF. The capping layer 330 may have a uniform thickness, but is not limited thereto. The capping layer 330 may be in contact with an upper surface of each of the plurality of color filters CF. An upper surface of the capping layer 330 may be exposed to the outside. In an embodiment, the capping layer 330 may not be located on the air grid pattern AP. The side surface of the capping layer 330 may be exposed by the trench TR. That is, the capping layer 330 may be provided in a plural quantity, and each of a plurality of capping layers 330 may be located on the plurality of color filters CF spaced apart from each other. However, the disclosure is not limited thereto, and the capping layer 330 may cover the air grid pattern AP. This will be later described in detail with reference to FIG. 10.

The capping layer 330 may prevent reflection of light such that the light incident from the outside may smoothly reach the photodiode PD. The capping layer 330 may include silicon oxide, but is not limited thereto. The capping layer 330 may be formed in a single layer or multiple layers.

An image sensor according to an embodiment may further include the reflection preventing structure 320 located on the second surface 400b of the substrate 400.

The reflection preventing structure 320 may be located between the second surface 400b of the substrate 400 and the plurality of color filters CF. The reflection preventing structure 320 may prevent the reflection of light such that the light incident on the second surface 400b of the substrate 400 may smoothly reach the photodiode PD. The upper surface 320_U of the reflection preventing structure 320 may be exposed by the trench TR. The air grid pattern AP may be located on the upper surface 320_U of the reflection preventing structure 320.

The reflection preventing structure 320 may include a first fixed charge layer 321, a second fixed charge layer 323 and a planarization layer 325 that are sequentially stacked on the second surface 400b of the substrate 400.

The first fixed charge layer 321, the second fixed charge layer 323, and the planarization layer 325 may include different materials. The first fixed charge layer 321 may include at least one of aluminum oxide, tantalum oxide, titanium oxide, and hafnium oxide. The second fixed charge layer 323 may include another one of aluminum oxide, tantalum oxide, titanium oxide and hafnium oxide. For example, the first fixed charge layer 321 may include aluminum oxide, the second fixed charge layer 323 may include hafnium oxide, and the planarization layer 325 may include silicon oxide. In some embodiments, an anti-reflection layer including silicon may be located between the second fixed charge layer 323 and the planarization layer 325. The anti-reflection layer may include, for example, silicon nitride.

An image sensor according to an embodiment may include the plurality of center color filters CCF that have a portion that has a convex shape with respect to the second surface 400b of the substrate 400. Accordingly, even if separate microlens are not located on the plurality of center color filters CCF, the light incident from the outside may be filtered and at the same time, may be refracted and concentrated. That is, the plurality of center color filters CCF may perform the function of a lens that refracts the light incident from the outside and transfer the refracted light to the plurality of photodiodes PD. In addition, the process of forming separate microlens on the plurality of center color filters CCF may be omitted, which may simplify the process.

In addition, the upper surfaces of the plurality of edge color filters ECF of an image sensor according to an embodiment may have a different shape from the upper surfaces of the plurality of center color filters CCF. Accordingly, the light incident on the central area CA and the edge area EA of the image sensor at a different angle may be concentrated to reach the center of each pixel, thereby improving an accuracy and a sensitivity of the image sensor.

In addition, the plurality of color filters CF of an image sensor according to an embodiment may be spaced apart from each other. In an embodiment, by the trench TR, the side surface of the plurality of color filters CF may be exposed to the outside, and external air may be located between the plurality of color filters CF. Therefore, a relative refractive index of the color filter CF may increase. Accordingly, the threshold angle of the color filters CF for total reflection may increase, and the light incident from the outside may be totally reflected to be effectively transferred to the plurality of photodiodes PD, thereby improving the accuracy and the sensitivity of the image sensor.

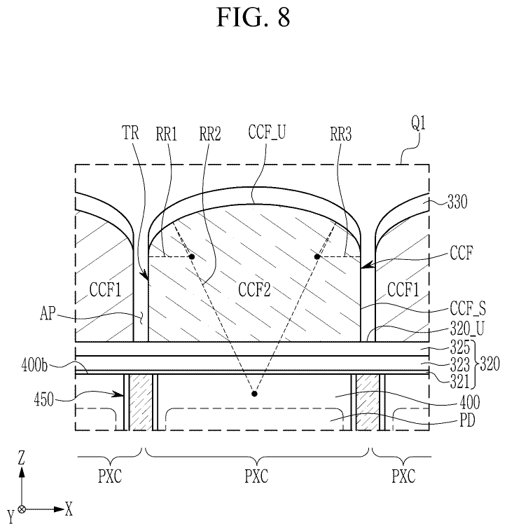

Hereinafter, the plurality of center color filters of an image sensor according to some embodiments will be described in detail with reference to FIG. 8 to FIG. 11. In the following embodiments, same reference numerals may refer to components overlapping with those of the previously described embodiments, and redundant descriptions will be omitted or simplified, and description will focus on differences.

FIG. 8 to FIG. 11 are cross-sectional views showing an image sensor according to some embodiments, corresponding to the region Q1 of FIG. 4.

Referring to FIG. 8, in some embodiments, the upper surface CCF_U of the plurality of center color filters CCF may have various shapes. For example, the upper surface CCF_U of the plurality of center color filters CCF may include a plurality of curved surfaces that have a first curvature radius RR1, a second curvature radius RR2, and a third curvature radius RR3. The second curvature radius RR2 may be greater than the first curvature radius RR1 and the third curvature radius RR3, but is not limited thereto. As another example, the upper surface CCF_U of the plurality of center color filters CCF may further include an inclined surface that is inclined at a predetermined angle from the second surface 400b of the substrate 400. As still another example, the upper surface CCF_U of the plurality of center color filters CCF may have a rectangular form that has a round edge.

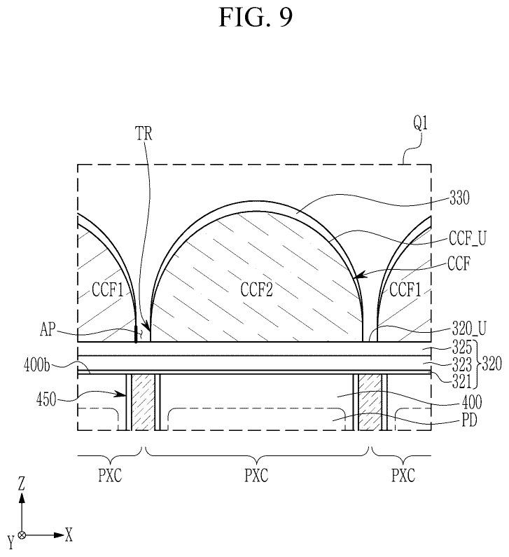

Referring to FIG. 9, in some embodiments, the side surface of the plurality of center color filters CCF may have various shapes. For example, the plurality of center color filters CCF may have a partial shape of a circle. That is, the side surface of the plurality of center color filters CCF may be formed as a curved surface. However, the disclosure is not limited thereto, as another example, the side surface CCF_S of the plurality of center color filters CCF may further include an inclined surface that is inclined at a predetermined angle from the second surface 400b of the substrate 400. As still another example, the side surface CCF_S of the plurality of center color filters CCF may have a rectangular form that has a round edge.

In the embodiment of FIG. 8 and FIG. 9, for better understanding and ease of description, only the shape of the plurality of center color filters CCF is described. Descriptions of the shape of the plurality of center color filters CCF in the embodiments of FIG. 8 and FIG. 9 may be applied to the shape of the plurality of edge color filters ECF.

Referring to FIG. 10, the capping layer 330 of an image sensor according to some embodiments may be located on the air grid pattern AP. The capping layer 330 may cover an upper portion of the air grid pattern AP. That is, the capping layer 330 may extend to be located on the plurality of center color filters CCF and the air grid pattern AP. A portion of the capping layer 330 located on the air grid pattern AP may include a bent portion 330B. The bent portion 330B may cover the air grid pattern AP. The bent portion 330B may have a concave shape toward the second surface 400b of the substrate 400. That is, a portion of the capping layer 330 located on the plurality of center color filters CCF may be conformally located along a profile of the upper surface CCF_U of the plurality of center color filters CCF, and the portion of the capping layer 330 located on the air grid pattern AP may have the concave shape toward the second surface 400b of the substrate 400. This may be due to process characteristics that the capping layer 330 may be formed together between the plurality of center color filters CCF during a process of forming the capping layer 330 on the plurality of center color filters CCF.

Accordingly, an image sensor according to some embodiments may further include an air gap AG located between the plurality of center color filters CCF. The air gap AG may be located between the plurality of center color filters CCF, and may refer to a portion of the air grid pattern AP covered by the capping layer 330. The air gap AG may be located between the plurality of center color filters CCF. The air gap AG may be located within a space defined by the side surface CCF_S of the plurality of center color filters CCF, the upper surface 320_U of the reflection preventing structure 320, and a lower surface of the capping layer 330. The capping layer 330 may cover the air gap AG. In some embodiments, the plurality of center color filters CCF may be spaced apart from each other by the air gap AG.

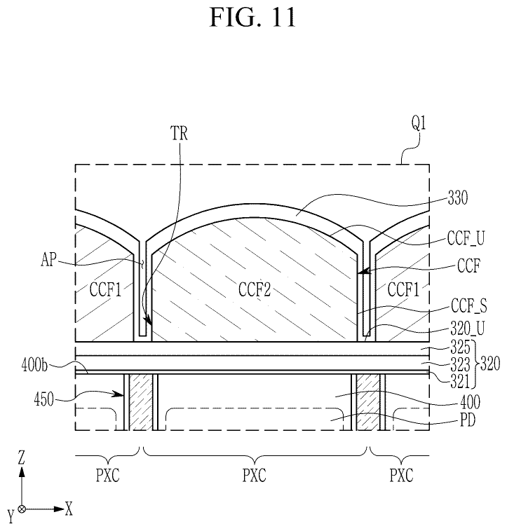

Referring to FIG. 11, in some embodiments, the capping layer 330 may be located within the trench TR. The capping layer 330 may be conformally located along an inner surface and the lower surface of the trench TR. That is, the capping layer 330 may be located on the upper surface CCF_U and the side surface CCF_S of the plurality of center color filters CCF, and the upper surface 320_U of the reflection preventing structure 320. Even in this case, the air grid pattern AP may be located between the capping layer 330 located on the side surface CCF_S of the plurality of center color filters CCF. In some embodiments, a side surface of the air grid pattern AP may be in contact with the capping layer 330, but is not limited thereto.

In the embodiment of FIG. 10 and FIG. 11, for better understanding and ease of description, only the shape of the capping layer 330 located on the plurality of center color filters CCF is described. Descriptions of the shape of the capping layer 330 in the embodiments of FIG. 10 and FIG. 11 may be applied to the shape of the capping layer 330 located on the plurality of edge color filters ECF.

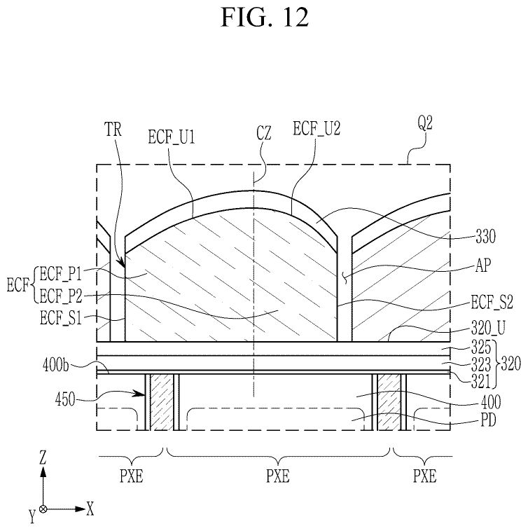

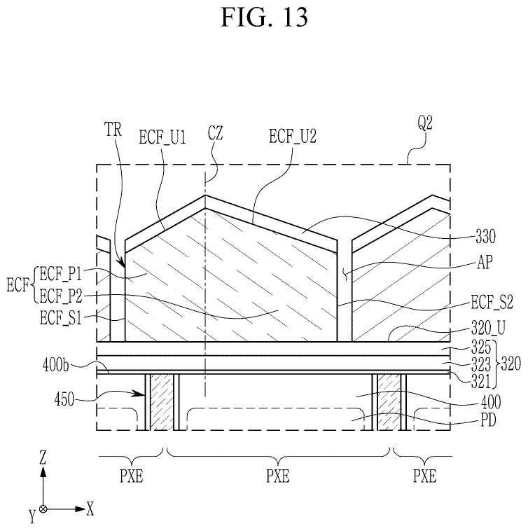

Hereinafter, a plurality of edge color filters of an image sensor according to some embodiments will be described in detail with reference to FIG. 12 and FIG. 13. In the following embodiments, same reference numerals may refer to components overlapping with those of the previously described embodiments, and redundant descriptions will be omitted or simplified, and description will focus on differences.

FIG. 12 and FIG. 13 are cross-sectional views showing an image sensor according to some embodiments, corresponding to the region Q2 of FIG. 6.

Referring to FIG. 12, the first curvature of the upper surface ECF_U1 of the first portion ECF_P1 of the plurality of edge color filters ECF of an image sensor according to some embodiments may be smaller than the second curvature of the upper surface ECF_U2 of the second portion ECF_P2. A width of the first portion ECF_P1 along the first direction (X direction) may be greater than a width of the second portion ECF_P2 along the first direction and/or the second direction (Y direction).

Referring to FIG. 13, the upper surfaces of the plurality of edge color filters ECF of an image sensor according to some embodiments may have various shapes. For example, as shown in FIG. 13, the upper surface ECF_U1 of the first portion ECF_P1 and the upper surface ECF_U2 of the second portion ECF_P2 may further include an inclined surface that is inclined at a predetermined angle from the second surface 400b of the substrate 400. An angle between the upper surface ECF_U1 of the first portion ECF_P1 and the second surface 400b of the substrate 400 may be greater than or equal to an angle between the upper surface ECF_U2 of the second portion ECF_P2 and the second surface 400b of the substrate 400, but is not limited thereto. As another example, the upper surface ECF_U1 of the first portion ECF_P1 and the upper surface ECF_U2 of the second portion ECF_P2 may include both a curved surface and an inclined surface.

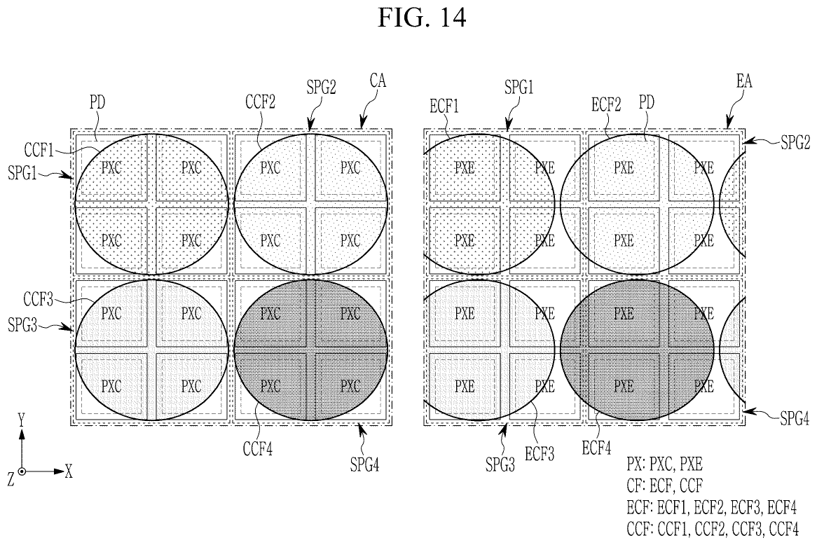

Hereinafter, an image sensor according to some embodiments will be described in detail with reference to FIG. 14.

FIG. 14 is a top plan view showing a central area and an edge area of an image sensor according to some embodiments. FIG. 14 is a top plan view showing a structure in which one color filter is located for every unit of 2×2 pixels.

Referring to FIG. 14, an image sensor according to some embodiments may include a plurality of sub-pixel groups SPG1 to SPG4. Each of first to fourth sub-pixel groups SPG1, SPG2, SPG3, and SPG4 may include four pixels PX. For example, each of the first to fourth sub-pixel groups SPG1, SPG2, SPG3, and SPG4 located in the central area CA may include four center pixels PXC, and each of the first to fourth sub-pixel groups SPG1, SPG2, SPG3, and SPG4 located in the edge area EA may include four edge pixels PXE. Each of the first to fourth sub-pixel groups SPG1, SPG2, SPG3, and SPG4 may overlap with one color filter CF in the third direction (Z direction). For example, the first sub-pixel group SPG1 located in the central area CA may overlap with the first center color filter CCF1 in the third direction (Z direction), a second sub-pixel group SPG2 located in the central area CA may overlap with the second center color filter CCF2 in the third direction (Z direction), a third sub-pixel group SPG3 located in the central area CA may overlap with the third center color filter CCF3 in the third direction (Z direction), and the fourth sub-pixel group SPG4 located in the central area CA may overlap with the fourth center color filter CCF4 in the third direction (Z direction). In addition, the first sub-pixel group SPG1 located in the edge area EA may overlap with the first edge color filter ECF1 in the third direction (Z direction), the second sub-pixel group SPG2 located in the edge area EA may overlap with the second edge color filter ECF2 in the third direction (Z direction), the third sub-pixel group SPG3 located in the edge area EA may overlap with the third edge color filter ECF3 in the third direction (Z direction), and the fourth sub-pixel group SPG4 located in the edge area EA may overlap with the fourth edge color filter ECF4 in the third direction (Z direction). However, this is merely an example, and the arrangement form of the color filter may vary. The plurality of center color filters CCF and the plurality of edge color filters ECF may have various shapes, examples of which are described above.

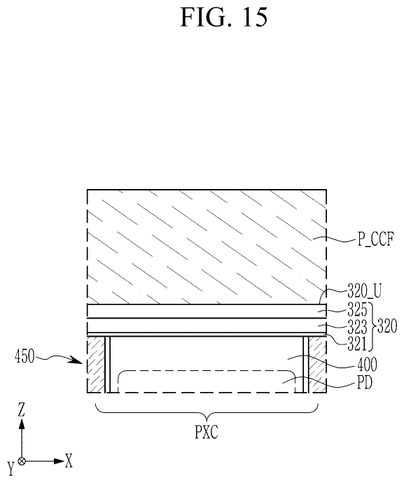

Hereinafter, a manufacturing method of an image sensor according to an embodiment will be described in detail with reference to FIG. 15 to FIG. 18.

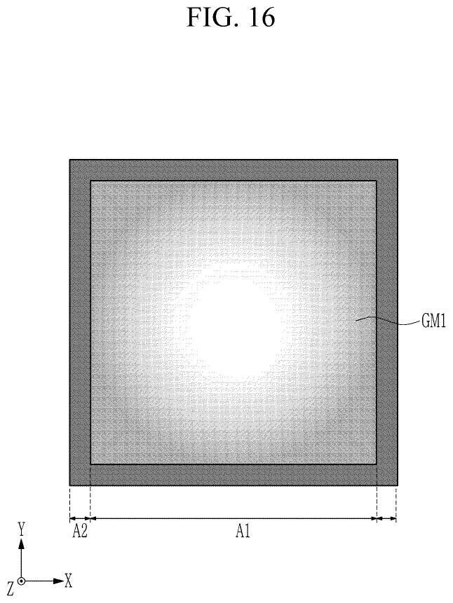

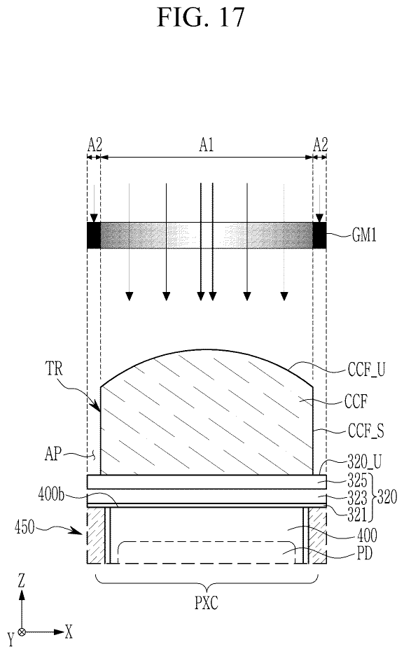

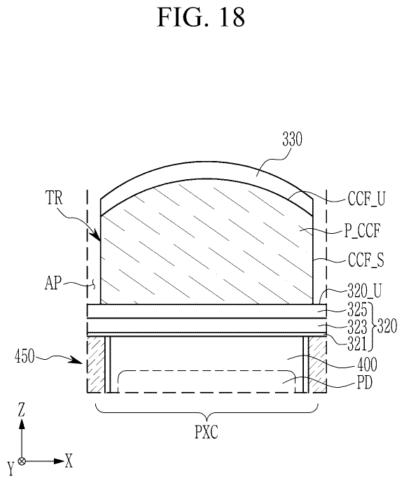

FIG. 15 is a cross-sectional view showing an intermediate step of a manufacturing method of a color filter according to an embodiment. FIG. 16 is a top plan view showing a mask of an image sensor according to an embodiment. FIG. 17 and FIG. 18 are cross-sectional views showing an intermediate step of a manufacturing method of a color filter according to an embodiment. In the following embodiments, same reference numerals may refer to components overlapping with those of the previously described embodiments, and redundant descriptions will be omitted or simplified, and description will focus on differences.

In the embodiment of FIG. 15 to FIG. 18, for better understanding and ease of description, the manufacturing method of one center color filter CCF is illustrated. Descriptions of the manufacturing method of the center color filter CCF in the embodiments of FIG. 15 to FIG. 18 may be applied to a manufacturing method of the plurality of edge color filters ECF.

First, referring to FIG. 15, the plurality of photodiodes PD may be formed within the substrate 400, and the pixel separation pattern 450 may be formed between the plurality of photodiodes PD. Subsequently, the first fixed charge layer 321, the second fixed charge layer 323 and the planarization layer 325 may be sequentially formed on the substrate 400, to form the reflection preventing structure 320. Subsequently, a color filter material layer P_CCF may be formed on the upper surface 320_U of the reflection preventing structure 320. The color filter material layer P_CCF may extend in the first direction (X direction) and the second direction (Y direction). The color filter material layer P_CCF may overlap with the plurality of photodiodes PD and the pixel separation pattern 450 in the third direction (Z direction). The color filter material layer P_CCF may include a negative photoresist material, but is not limited thereto.

Subsequently, referring to FIG. 16 and FIG. 17, a gray mask pattern GM1 may be formed on the color filter material layer P_CCF, and at least a portion of the color filter material layer P_CCF may be etched by using the gray mask pattern GM1 as a mask.

The gray mask pattern GM1 may include a first area A1 located in a central portion and a second area A2 surrounding the first area A1. The first area A1 may be located in the generally central portion of the gray mask pattern GM1, and the second area A2 may be located in a generally edge portion of the gray mask pattern GM1. The first area A1 may include portions having different light transmittance (optical density). For example, the first area A1 may be a grayscale mask pattern. The light transmittance of the first area A1 may increase toward a center of the gray mask pattern GM1.

Accordingly, when the color filter material layer P_CCF is patterned by using the gray mask pattern GM1 as a mask according to an embodiment, since the color filter material layer P_CCF includes a negative photoresist material, a portion of the color filter material layer P_CCF corresponding to the second area A2 may be completely removed to form the trench TR. In addition, a portion of the color filter material layer P_CCF corresponding to the first area A1 may be etched to a round shape, thereby forming the center color filter CCF. That is, in an embodiment, the center color filter CCF may have a portion that has a convex shape with respect to the second surface 400b of the substrate 400. For example, the upper surface CCF_U of the center color filter CCF may include a curved surface that is convex with respect to the second surface 400b of the substrate 400. In addition, as the trench TR is formed, the air grid pattern AP may be formed between the plurality of center color filters CCF. In addition, the side surface CCF_S of the center color filter CCF may be exposed.

Finally, referring to FIG. 18, the capping layer 330 may be formed on the upper surface CCF_U of the center color filter CCF. The capping layer 330 may be conformally formed on the center color filter CCF. The capping layer 330 may not be formed in an upper portion of the trench TR, but is not limited thereto. For example, like the embodiment of FIG. 10, the capping layer 330 may be formed in an upper portion of the center color filter CCF and the trench TR, to form the air gap AG. As another example, like the embodiment of FIG. 11, the capping layer 330 may be conformally formed on a lower surface and an inner sidewall of the trench TR. The capping layer 330 may prevent the reflection of light such that the light incident from the outside may smoothly reach the photodiode PD. The capping layer 330 may include silicon oxide, but is not limited thereto. The capping layer 330 may be formed in a single layer or multiple layers. Accordingly, the image sensor according to one or more embodiments of FIG. 1 to FIG. 7 may be formed.

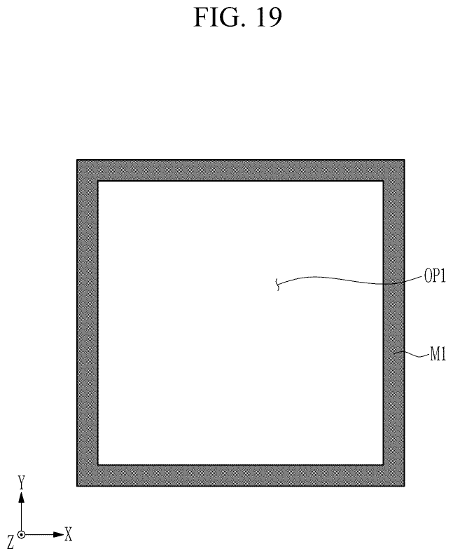

Hereinafter, a manufacturing method of an image sensor according to some embodiments will be described in detail with reference to FIG. 19 to FIG. 25.

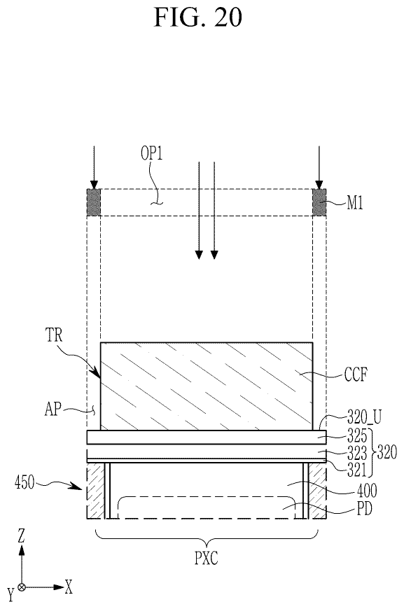

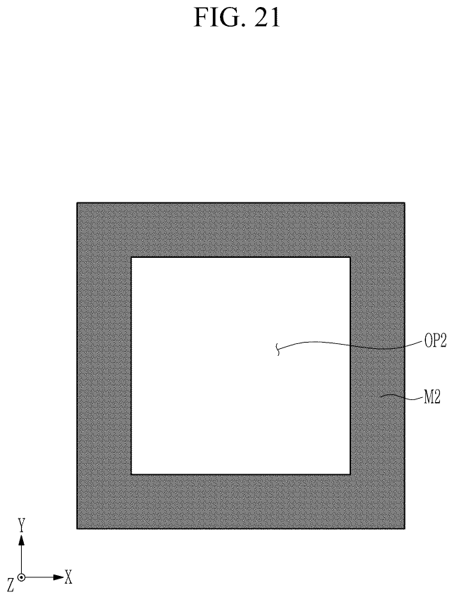

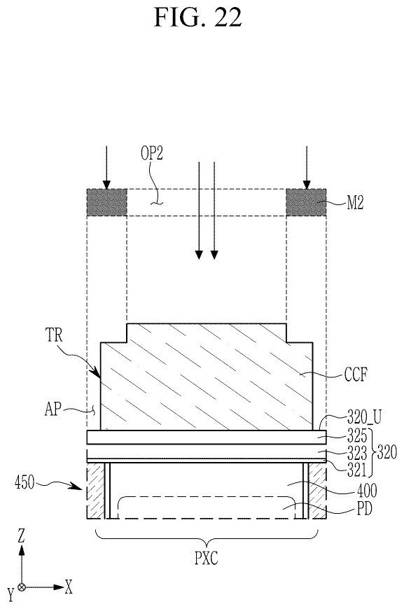

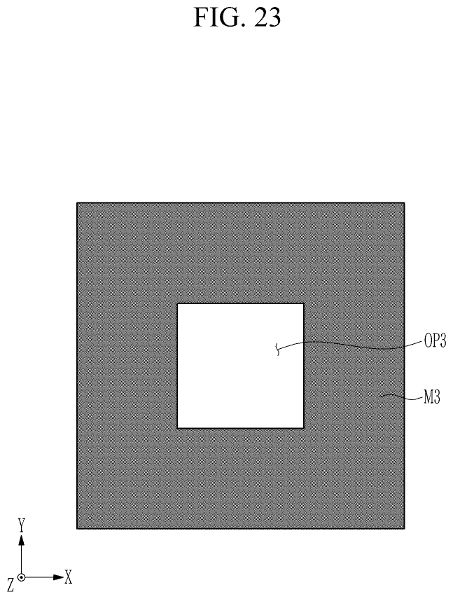

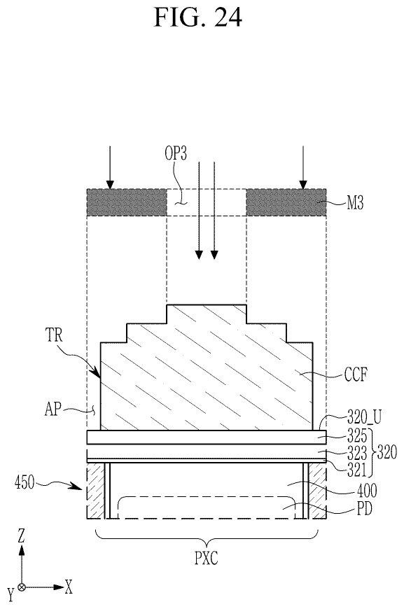

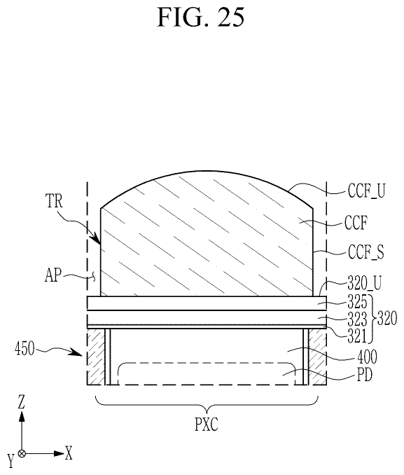

FIG. 19 is a top plan view showing a mask of an image sensor according to some embodiments. FIG. 20 is a cross-sectional view showing an intermediate step of a manufacturing method of a color filter according to some embodiments. FIG. 21 is a top plan view showing a mask of an image sensor according to some embodiments. FIG. 22 is a cross-sectional view showing an intermediate step of a manufacturing method of a color filter according to some embodiments. FIG. 23 is a top plan view showing a mask of an image sensor according to some embodiments. FIG. 24 and FIG. 25 are cross-sectional views showing an intermediate step of a manufacturing method of a color filter according to some embodiments. In the following embodiments, same reference numerals may refer to components overlapping with those of the previously described embodiments, and redundant descriptions will be omitted or simplified, and description will focus on differences.

The embodiments of FIG. 19 to FIG. 25 represent a method of forming the center color filter CCF by repeating a process twice or more. In the embodiment of FIG. 19 to FIG. 25, for better understanding and ease of description, the manufacturing method of one center color filter CCF is illustrated, but descriptions of the manufacturing method of the center color filter CCF in the embodiments of FIG. 19 to FIG. 25 may be applied to a manufacturing method of a plurality of center color filters CCF as well as a manufacturing method of a plurality of edge color filters ECF.

First, the plurality of photodiodes PD may be formed within the substrate 400, and the pixel separation pattern 450 may be formed between the plurality of photodiodes PD. Afterwards, the reflection preventing structure 320 may be formed on the substrate 400, and the color filter material layer may be formed on the upper surface 320_U of the reflection preventing structure 320. The description on the color filter material layer may be substantially the same as or similar to that of the color filter material layer P_CCF (see FIG. 15) of the embodiment of FIG. 15 to FIG. 18, and may be omitted.

Subsequently, referring to FIG. 19 and FIG. 20, a first mask pattern M1 having a first open portion OP1 may be formed on the color filter material layer P_CCF, and the center color filter CCF may be formed by patterning the color filter material layer by using the first mask pattern M1 as a mask.

In this case, since the color filter material layer P_CCF includes a negative photoresist material, a portion of the color filter material layer corresponding to the first open portion OP1 may not be removed. In addition, a portion of the color filter material layer corresponding to the first mask pattern M1 may be completely removed to form the trench TR. Accordingly, the center color filter CCF may be formed. By the trench TR, the air grid pattern AP may be formed between the center color filter CCF. In addition, the side surface CCF_S of the center color filter CCF may be exposed.

Subsequently, referring to FIG. 21 and FIG. 22, a second mask pattern M2 having a second open portion OP2 may be formed on the center color filter CCF, and the center color filter CCF may be patterned by using the second mask pattern M2 as a mask.

The second open portion OP2 may have a smaller area than the first open portion OP1. At least a portion of the first open portion OP1 may overlap with the second open portion OP2 in the third direction (Z direction), and a remaining portion of the first open portion OP1 may not overlap with the second open portion OP2 in the third direction (Z direction). Accordingly, at least a portion of the center color filter CCF corresponding to the second mask pattern M2 may be etched such that the center color filter CCF may have a step. A portion of the center color filter CCF corresponding to the second open portion OP2 may not be removed.

Subsequently, referring to FIG. 23 to FIG. 25, a third mask pattern M3 having a third open portion OP3 may be formed on the center color filter CCF, and the center color filter CCF may be patterned by using the third mask pattern M3 as a mask.

The third open portion OP3 may have a smaller area than the second open portion OP2. At least a portion of the second open portion OP2 may overlap with the third open portion OP3 in the third direction (Z direction), and a remaining portion of the second open portion OP2 may not overlap with the third open portion OP3 in the third direction (Z direction). Accordingly, at least a portion of the center color filter CCF corresponding to the third mask pattern M3 may be etched such that the center color filter CCF may have an additional step. A portion of the center color filter CCF corresponding to the third open portion OP3 may not be removed.

FIG. 22 and FIG. 24 illustrate that the center color filter CCF has a step in a cross-section in order to distinguish a region of the center color filter CCF formed in each step. However, an actual shape of the center color filter CCF may have a curved surface that is convex with respect to the second surface 400b of the substrate 400, as shown in FIG. 25. This is because, when forming the center color filter CCF at each step, the center color filter CCF may flow to neighboring portions to form a natural curved surface.

Finally, by forming the capping layer 330 on the center color filter CCF, the center color filter CCF according to one or more embodiments of FIG. 1 to FIG. 7 may be formed.

According to an embodiment, the plurality of color filters may have a portion that has convex shape with respect to the upper surface of the substrate. In addition, upper surfaces of the plurality of edge color filters may have different shapes (e.g., different curvatures) compared with upper surfaces of the plurality of center color filters. Accordingly, an accuracy and a sensitivity of the image sensor may be improved.

In addition, the plurality of color filters may be spaced apart from each other by an air grid pattern. Accordingly, a threshold angle of the plurality of color filters for total reflection may increase, and light incident from the outside may be totally reflected to be effectively transferred to the plurality of photodiodes, thereby improving the accuracy and the sensitivity of the image sensor.

While the embodiment of the disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An image sensor, comprising:
a substrate comprising a central area and an edge area surrounding the central area, the substrate comprising a plurality of photodiodes in the central area and the edge area;
a plurality of center color filters provided on the plurality of photodiodes in the central area;
a plurality of edge color filters provided on the plurality of photodiodes in the edge area; and
an air grid pattern provided between the plurality of center color filters and/or between the plurality of edge color filters,
wherein portions of the plurality of center color filters have a convex shape with respect to an upper surface of the substrate, and
wherein upper surfaces of the plurality of edge color filters have a different shape from upper surfaces of the plurality of center color filters.

2. The image sensor of claim 1, wherein each edge color filter of the plurality of edge color filters comprises a first portion and a second portion,
wherein an upper surface of the first portion has a first curvature, and
wherein an upper surface of the second portion has a second curvature different from the first curvature.

3. The image sensor of claim 2, wherein the first portion is closer to the plurality of center color filters than the second portion, and
wherein the first curvature is greater than the second curvature.

4. The image sensor of claim 3, wherein the upper surfaces of the plurality of center color filters comprise a curved surface having a third curvature, and
wherein the third curvature is smaller than the first curvature.

5. The image sensor of claim 3, wherein a width of the first portion is smaller than a width of the second portion.

6. The image sensor of claim 2, wherein a center of an edge color filter is spaced apart from a center of a corresponding photodiode in a horizontal direction.

7. The image sensor of claim 1, wherein the upper surfaces of the plurality of center color filters and the upper surfaces of the plurality of edge color filters have a curved surface that is convex with respect to the upper surface of the substrate.

8. The image sensor of claim 1, wherein portions of the plurality of edge color filters have a convex shape with respect to the upper surface of the substrate, and
wherein the upper surfaces of the plurality of edge color filters comprise a plurality of inclined surfaces.

9. The image sensor of claim 1, wherein the plurality of center color filters are spaced apart from each other, and the plurality of edge color filters are spaced apart from each other.

10. The image sensor of claim 9, further comprising a capping layer provided on the plurality of center color filters,
wherein the capping layer covers the air grid pattern.

11. The image sensor of claim 9, further comprising a capping layer provided on the plurality of center color filters,
wherein the capping layer covers a side surface of the plurality of center color filters.

12. The image sensor of claim 11, further comprising a reflection preventing structure provided between the substrate and the plurality of center color filters and between the substrate and the plurality of edge color filters,
wherein the air grid pattern is provided on an upper surface of the reflection preventing structure.

13. The image sensor of claim 12, wherein the air grid pattern is in contact with the side surface of the plurality of center color filters.

14. An image sensor, comprising:
a substrate comprising a plurality of photodiodes;
a plurality of color filters provided on the plurality of photodiodes and spaced apart from each other, wherein portions of the plurality of color filters have a curved surface that is convex with respect to an upper surface of the substrate; and
an air grid pattern provided between the plurality of color filters.

15. The image sensor of claim 14, further comprising a reflection preventing structure provided between the substrate and the plurality of color filters,
wherein the air grid pattern is provided on an upper surface of the reflection preventing structure.

16. The image sensor of claim 15, further comprising a pixel separation pattern provided between the plurality of photodiodes,
wherein a width of the air grid pattern is smaller than or equal to a width of the pixel separation pattern.

17. The image sensor of claim 14, further comprise capping layers provided on the plurality of color filters, respectively, and spaced apart from each other.

18. The image sensor of claim 17, wherein the capping layers cover the air grid pattern.

19. An image sensor, comprising:
a substrate comprising a central area and an edge area surrounding the central area, the substrate comprising a plurality of photodiodes in the central area and the edge area;
a plurality of center color filters provided on the plurality of photodiodes in the central area, the plurality of center color filters being spaced apart from each other;
a plurality of edge color filters provided on the plurality of photodiodes in the edge area, the plurality of edge color filters being spaced apart from each other;
capping layers provided on the plurality of center color filters and the plurality of edge color filters, respectively, the clapping layers being spaced apart from each other; and
an air grid pattern provided between the plurality of center color filters and/or between the plurality of edge color filters,
wherein upper surfaces of the plurality of center color filters comprise a curved surface that is convex with respect to an upper surface of the substrate,
wherein each edge color filter of the plurality of edge color filters comprises a first portion and a second portion,
wherein an upper surface of the first portion has a first curvature; and
wherein an upper surface of the second portion has a second curvature different from the first curvature.

20. The image sensor of claim 19, further comprising a reflection preventing structure provided between the substrate and the plurality of center color filters and between the substrate and the plurality of edge color filters,
wherein the air grid pattern is provided on an upper surface of the reflection preventing structure, and configured to expose at least a portion of a side surface of the plurality of center color filters.
